(19) United States
(12) Patent Application Publication
(10) Pub. No.: US 2006/0223011 A1
(43) Pub. Date: Oct. 5, 2006

(54) Method for manufacturing optical semiconductor element, and optical semiconductor element

(75) Inventor: Tsuyoshi Kaneko, Shimosuwa (JP)

Correspondence Address: HARNESS, DICKEY & PIERCE, P.L.C., P.O. BOX 828, BLOOMFIELD HILLS, MI, 48303, US

(73) Assignee: Seiko Epson Corporation

(21) Appl. No.: 11/366,720

(22) Filed: Mar. 2, 2006

(30) Foreign Application Priority Data
Apr. 1, 2005 (JP) 2005-106036

(51) Int. Cl. G03F 7/00

(52) U.S. Cl. 430/316; 430/311; 430/313

(57) ABSTRACT

A method for manufacturing an optical semiconductor element having a light emitting element section and a functional section. The method includes conducting dry etching, and then conducting wet etching, when forming at least a part of the functional section.

The entire disclosure of Japanese Patent Application No. 2005-106036, filed Apr. 1, 2005 is expressly incorporated by reference herein.

### BACKGROUND

1. Technical Field

The present invention relates to methods for manufacturing optical semiconductor elements, and optical semiconductor elements.

2. Related Art

A surface-emitting type semiconductor laser (hereafter referred to as a “surface-emitting laser”) has a smaller device volume compared to an ordinary edge-emitting type semiconductor laser, such that the electrostatic breakdown voltage of the device itself is low. For this reason, the device may be damaged by static electricity caused by a machine or an operator in a mounting process. In particular, a surface-emitting laser has a certain tolerance to a forward bias voltage, but has a low tolerance to a reverse bias voltage, and the device may be destroyed when a reverse bias voltage is impressed. A variety of measures are usually implemented in a mounting process to remove static electricity, but these measures have limitations. For example, Japanese Laid-open Patent Application JP-A-2004-6548 describes an example of related art.

To improve the electrostatic breakdown tolerance of a surface-emitting laser, a structure that integrates the surface-emitting laser and an electrostatic breakdown protection element (functional section) has been considered. A diode having a rectification function may be enumerated as an electrostatic breakdown protection element. In other words a diode is connected in a reverse direction with respect to and in parallel with a surface-emitting laser. By so doing, when a reverse bias voltage is impressed due to static electricity to the surface-emitting laser, a current path can be secured by the diode, and an excessive bias voltage can be prevented from acting on the surface-emitting laser.

A method described below has been devised as a method for manufacturing a surface-emitting laser element having such a functional section as described above.
a) First, layers that become to be a surface-emitting laser are formed on a substrate, and other layers that become to be a functional section are formed on the layers by epitaxial growth.
b) Then, a functional section is formed by patterning the other layers that become to be a functional section.
c) Then, a surface-emitting laser is formed by patterning the layers that become to be a surface-emitting laser.
d) Then, electrodes that drive the surface-emitting laser are formed.
e) Then, electrodes that electrically connect the functional section with the surface-emitting laser are formed. By these steps, a surface-emitting laser element having a functional section is completed.

If the other layers that become to be a surface-emitting laser are etched at the time of patterning the layers that become to be a functional section, the reflectivity of a distributed reflection type multilayer mirror may be changed from its original design. In other words, a surface-emitting laser with a desired characteristic cannot be formed. When a dry etching method is used in the step b), it is difficult to form a functional section without damaging the layers that become to be a surface-emitting laser.

A manufacturing method in which layers that become to be a surface-emitting laser are completely remained has been devised. According to this manufacturing method, an uppermost layer among layers that become to be a surface-emitting laser is formed with GaAs and a part (lowermost layer) among layers that become to be a functional section is formed with AlGaAs in the step a). Further, wet etching is conducted with an etchant that etches only AlGaAs in the step b).

However, even in the manufacturing method described above, when the functional section is patterned by wet etching, not only the upper surface of the layers that become to be a functional section is etched, but etching of the side surface in a transverse direction (in a plane direction) also advances. Accordingly, it is difficult for the manufacturing method described above to accurately pattern the functional section.

### SUMMARY

In accordance with an advantage of some aspects of the invention, in the process for manufacturing an optical semiconductor element having a light emitting element section and a functional section, an optical semiconductor element and a method for manufacturing an optical semiconductor element which enable accurate patterning are provided.

In accordance with another advantage of some aspects of the invention, in the process for manufacturing an optical semiconductor element having a light emitting element section and a functional section, an optical semiconductor element and a method for manufacturing an optical semiconductor element which enable simple and accurate patterning of layers that become to be a functional section without damaging layers for forming a light emitting element section are provided.

An embodiment of a method for manufacturing an optical semiconductor element pertains to a method for manufacturing an optical semiconductor element having a light emitting element section and a functional section, and includes conducting dry etching, and then conducting wet etching, when forming at least a part of the functional section.

According to the present embodiment, layers that become to be a functional section can be accurately patterned in a plane direction of the layers by the dry etching. However, it is difficult to control the amount of etching of the layers in the depth direction only by the dry etching. According to the present embodiment, the amount of etching in the depth direction can be accurately and readily controlled by the wet etching that is conducted after the dry etching. Accordingly, in accordance with the present embodiment, a part or all of the functional section can be accurately patterned by the dry etching and the wet etching.

In accordance with another embodiment of the invention, a method for manufacturing an optical semiconductor element includes: a first process of forming, above a substrate, a first semiconductor layer composed of a first conductivity type, a second semiconductor layer that functions as an active layer, a third semiconductor layer composed of a second conductivity type and a fourth semiconductor layer; a second process of forming at least a part of a functional section by patterning at least a part of the fourth semiconductor layer; a third process of forming the functional section and a light emitting element section by patterning at least the third semiconductor layer; a fourth process of forming first and second electrodes for driving the light emitting element section; and a fifth process of forming a third electrode that connects the light emitting element section with the functional section, wherein dry etching is conducted and thereafter wet etching is conducted in the second process to thereby form at least a part of the functional section.

According to the present embodiment, in the first process, for example, layers that become to be a surface-emitting laser (surface-emitting laser layers) can be formed on a substrate, and layers that become to be a functional section (functional layers) can be formed on the surface-emitting laser layers. Further, in the second process, a part of the functional section can be formed. In the second process, a pattern for forming a part of the functional section can be accurately etched in its plane direction by dry etching, and the pattern can be accurately etched in its depth direction by wet etching. Therefore, in accordance with the present embodiment, the layers that become to be a functional section can be readily and accurately patterned without damaging the layers that become to be a light emitting element section. Accordingly, an optical semiconductor element equipped with a light emitting element section and a functional section can be highly accurately manufactured.

Further, in the method for manufacturing an optical semiconductor element in accordance with an aspect of the embodiment, the dry etching and the wet etching may preferably be continuously conducted.

In accordance with the present embodiment, the amount of etching in the plane direction can be accurately controlled by the dry etching, and the amount of etching in the depth direction can be accurately controlled by the wet etching. Also, a common resist can be used in both of the dry etching and the wet etching. Therefore, in accordance with the present embodiment, the functional section can be accurately formed without damaging layers for forming the light emitting element section.

Also, in the method for manufacturing an optical semiconductor element in accordance with another aspect of the embodiment, a major part of a designed portion (to be etched) may preferably be etched by the dry etching, and a remaining minor portion of the designed portion may preferably be etched by the wet etching.

According to the present embodiment, the amount of etching by the wet etching is small, such that disturbance in the pattern configuration, which may be caused by etching that advances in a transverse direction (i.e., a plane direction) by the wet etching, can be avoided. Wet etching causes etching to advance not only in a depth direction but also in a horizontal direction. Therefore, if the entire etching is conducted by wet etching alone, disturbance in the pattern configuration, such as, an overhang at a side face (boundary) of the etching pattern and the like may occur, which may result in inconveniences such as disconnection of the electrodes, changes in the element capacitance, and the like. In accordance with the present embodiment, the amount of wet etching is small, compared to the amount of dry etching, such that the inconveniences described above can be substantially eliminated. Also, in accordance with the present embodiment, the amount of etching in a depth direction can be accurately controlled by a small amount of wet etching. Therefore, in accordance with the present embodiment, layers that become to be a functional section can be readily and accurately patterned without damaging layers for forming a light emitting element section.

Also, in the method for manufacturing an optical semiconductor element in accordance with another aspect of the embodiment, the thickness to be etched by the wet etching may preferably be 0.1 μm or less.

According to the present embodiment, the amount of wet etching is minute, such that disturbance in the pattern configuration by the wet etching can be avoided. Also, the amount of etching in a depth direction as small as 0.1 μm or less can be accurately controlled by the wet etching.

Also, in the method for manufacturing an optical semiconductor element in accordance with another aspect of the embodiment, a removal step may preferably be conducted between the dry etching and the wet etching to remove a deteriorated layer that is generated after the dry etching.

According to the present embodiment, a deteriorated layer that is generated by dry etching can be removed by the removal step. Further, by conducting wet etching after the removal step, layers that become to be a functional section can be readily and accurately patterned without damaging layers for forming a light emitting element section.

Also, in the method for manufacturing an optical semiconductor element in accordance with another aspect of the embodiment, the wet etching may preferably include a removal step to remove a deteriorated layer that is generated after the dry etching.

According to the present embodiment, a deteriorated layer that is generated by dry etching can be removed by the wet etching. Therefore, according to the present embodiment, the manufacturing process can be simplified and made faster.

Further, in the method for manufacturing an optical semiconductor element in accordance with another aspect of the embodiment, the removal step may preferably be a process with a mixed solution of ammonia water and hydrogen peroxide water. Also, the removal step may be conducted by using ultraviolet ray or plasma.

Also, in the method for manufacturing an optical semiconductor element in accordance with another aspect of the embodiment, the light emitting element section may preferably be a surface-emitting laser, and the functional section may preferably be a diode that protects the surface-emitting laser from electrostatic breakdown.

According to the present embodiment, a surface-emitting laser with high performance and high reliability that is highly tolerable to static electricity can be manufactured. Also, the functional section may be a light receiving element (e.g., a photodiode) that monitors an output of the surface-emitting laser.

Also, in the method for manufacturing an optical semiconductor element in accordance with another aspect of the embodiment, the wet etching may preferably be conducted using hydrofluoric acid with a concentration of 1% or less.

According to the present embodiment, the wet etching can be readily conducted.

Also, in the method for manufacturing an optical semiconductor element in accordance with another aspect of the embodiment, a layer to be removed by the wet etching and a layer below the layer to be removed may preferably have different aluminum compositions.

According to the present embodiment, by using the difference in aluminum composition between a layer to be etched (i.e., a layer to be removed) and a layer not to be etched (lower layer), wet etching can be conducted with an etchant having a high selection ratio, and the layer not to be etched (e.g., a surface of the surface-emitting laser) can be securely exposed.

Also, in the method for manufacturing an optical semiconductor element in accordance with another aspect of the embodiment, the fourth semiconductor layer may preferably include a layer of AlGaAs, and the AlGaAs may be expressed by AlₓGa₁₋ₓAs, wherein X may be 0.3 or greater.

According to the present embodiment, by using the difference in aluminum composition between a layer to be etched (i.e., the fourth semiconductor layer) and a layer not to be etched (i.e., the third semiconductor layer) in wet etching, the fourth semiconductor layer alone can be securely etched.

Also, in the method for manufacturing an optical semiconductor element in accordance with another aspect of the embodiment, the fourth semiconductor layer may preferably include a GaAs layer and an AlGaAs layer formed below the GaAs layer, and the AlGaAs layer may preferably be thinner than the GaAs layer.

According to the present embodiment, for example, the GaAs layer of the fourth semiconductor layer can be entirely etched by dry etching, and the AlGaAs layer of the fourth semiconductor layer can be entirely etched by wet etching. Also, if the GaAs layer of the fourth semiconductor layer is almost entirely etched by dry etching, the remaining portion of the GaAs layer and the entire AlGaAs layer of the fourth semiconductor layer can be etched by wet etching. Also, if the entire GaAs layer and a portion of the AlGaAs layer of the fourth semiconductor layer are etched by dry etching, the remaining portion of the AlGaAs layer of the fourth semiconductor layer can be etched by wet etching. Accordingly, even when the dry etching stops at the GaAs layer of the fourth semiconductor layer or advances to the AlGaAs layer, the AlGaAs layer can be accurately etched by the wet etching.

In accordance with another embodiment of the invention, an optical semiconductor element is manufactured by any one of the methods for manufacturing an optical semiconductor element described above.

According to the present embodiment, a high performance optical semiconductor element equipped with a light emitting element section and a functional section can be provided at low cost.

### BRIEF DESCRIPTION OF THE DRAWINGS

FIG. 1 is a plan view of an optical semiconductor element in accordance with an embodiment of the invention.

FIG. 2 is a cross-sectional view in part of the optical semiconductor element.

FIG. 3 is a circuit diagram of the optical semiconductor element.

FIG. 4 is a cross-sectional view schematically showing a step of a method for manufacturing an optical semiconductor element in accordance with another embodiment of the invention.

FIG. 5 is a cross-sectional view schematically showing a step of the method for manufacturing an optical semiconductor element in accordance with the other embodiment of the invention.

FIG. 6 is a cross-sectional view schematically showing a step of the method for manufacturing an optical semiconductor element in accordance with the other embodiment of the invention.

FIG. 7 is a plan view indicating a problematical area in wet etching.

FIG. 8 is a cross-sectional view indicating a portion of the problematical area in wet etching.

FIG. 9 is a plan view indicating an effective area of etching in accordance with the embodiment of the invention.

FIG. 10 is a cross-sectional view indicating a portion of the effective area in accordance with the embodiment of the invention.

FIG. 11 is a view showing an example of a deteriorated layer that is generated in a dry etching process.

FIG. 12 is a view showing an example of a state in which the step of removing the deteriorated layer has been conducted.

FIG. 13 is a cross-sectional view schematically showing a method for manufacturing an optical semiconductor element in accordance with a first exemplary embodiment of the invention.

FIG. 14 is a cross-sectional view schematically showing a method for manufacturing an optical semiconductor element in accordance with a second exemplary embodiment of the invention.

FIG. 15 is a view showing an optical transmission device in accordance with an embodiment of the invention.

FIG. 16 is a view showing a usage configuration of the optical transmission devices.

### DESCRIPTION OF EXEMPLARY EMBODIMENTS

A method for manufacturing an optical semiconductor element in accordance with a preferred embodiment of the invention and an optical semiconductor element in accordance with a preferred embodiment of the invention are described below with reference to the accompanying drawings. The present embodiment is described with reference to a surface-emitting laser as an example of the optical semiconductor element.

Optical Semiconductor Element

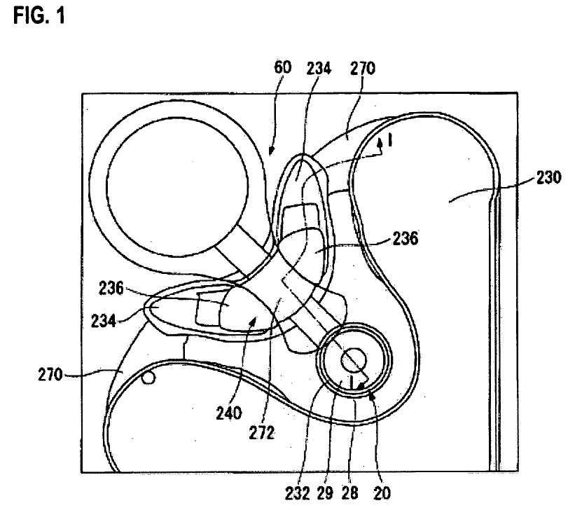

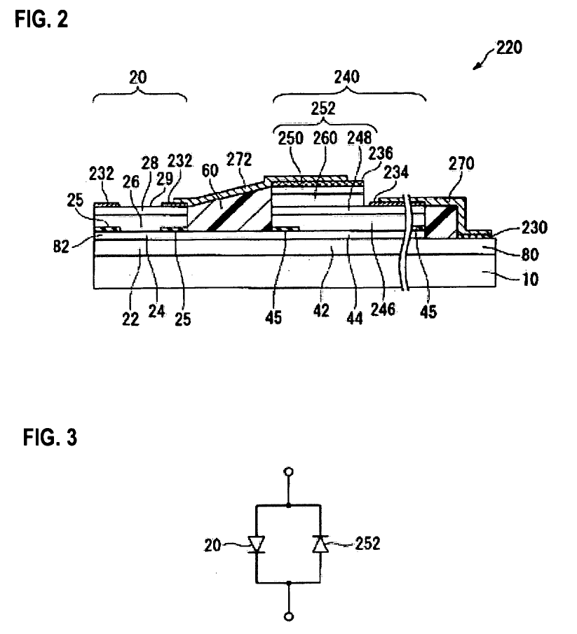

FIG. 1 is a plan view of an optical semiconductor element 220 in accordance with an embodiment of the invention. FIG. 2 is a cross-sectional view of a portion of the optical semiconductor element taken along a line I-I of FIG. 1. FIG. 3 is a circuit diagram of the optical semiconductor element in accordance with the embodiment.

The optical semiconductor element 220 is composed of a substrate 10, a light emitting element section 20, and a rectification element section (functional section) 240. The light emitting element section 20 composes a surface-emitting laser.

The substrate 10 is a semiconductor substrate (for example, an n-type GaAs substrate). The substrate 10 supports the light emitting element section 20 and the rectification element section 240. In other words, the light emitting element section 20 and the rectification element section 240 are formed on the same substrate (the same chip), and has a monolithic structure.

The light emitting element section 20 is formed on the substrate 10. A single light emitting element section 20 may be formed on a single substrate 10, or a plurality of light emitting element sections 20 may be formed thereon. An upper surface of the light emitting element section 20 defines a light emission surface 29. The light emitting element section 20 has a plane configuration that is a circular shape, but is not limited to this shape. In the case of a surface-emitting laser, the light emitting element section 20 is called a vertical resonator.

The light emitting element section 20 includes a first semiconductor layer 22 of a first conductivity type (for example, n-type), a second semiconductor layer 24 that functions as an active layer, and third semiconductor layers 26 and 28 of a second conductivity type (for example, p-type), which are disposed successively from the side of the substrate 10.

The first semiconductor layer 22 may be composed of, for example, a distributed reflection type multilayer mirror of 40 pairs of alternately laminated n-type Al_{0.9}Ga_{0.1}As layers and n-type Al_{0.15}Ga_{0.85}As layers (first mirror). The second semiconductor layer 24 may be composed of, for example, GaAs well layers and Al_{0.3}Ga_{0.7}As barrier layers in which the well layers include a quantum well structure composed of three layers. The third semiconductor layer 26 may be composed of, for example, a distributed reflection type multilayer mirror of 25 pairs of alternately laminated p-type Al_{0.9}Ga_{0.1}As layers and p-type Al_{0.15}Ga_{0.85}As layers (second mirror). Also, the third semiconductor layer 28 at the topmost surface may be a contact section composed of, for example, p-type GaAs layers. It is noted that the composition of each of the layers and the number of the layers forming the first semiconductor layer 22, the second semiconductor layer 24, and the third semiconductor layers 26 and 28 are not limited to the above.

The third semiconductor layers 26 and 28 are formed to be p-type by doping C, Zn, Mg or the like. The first semiconductor layer 22 is formed to be n-type by doping Si, Se or the like. Accordingly, the third semiconductor layers 26 and 28, the second semiconductor layer 24 that is not doped with an impurity, and the first semiconductor layer 22 form a pin diode.

A dielectric layer 25 is formed in a region near the second semiconductor layer 24 that functions as an active layer among the layers composing the third semiconductor section 26. The dielectric layer 25 functions as a current constricting layer. The dielectric layer 25 may be formed, for example, in a ring shape along the circumference of the plane configuration of the light emitting element section 20. The dielectric layer 25 can be formed from aluminum oxide as a main component.

First and second electrodes 230 and 232 for driving are formed at the light emitting element section 20.

The first electrode 230 is electrically connected to the first semiconductor layer 22, and may be formed, for example, on a portion that is continuous from the first semiconductor layer 22 (on a first semiconductor layer 80 shown in FIG. 2). As shown in FIG. 1, the first electrode 230 is formed outside the third semiconductor section 28 (the light emission surface 29), and extends in a manner, for example, to encircle ⅔ of the outer circumference of the third semiconductor layer 28. The first electrode 230 can be formed from a multilayer film of, for example, Au and an alloy of Au and Ge.

On the other hand, the second electrode 232 is electrically connected to the third semiconductor layers 26 and 28, and may be formed, for example, on the third semiconductor layer 28 that is a contact section. As shown in FIG. 1, the second electrode 232 may be formed in a ring shape along an edge section of the upper surface of the third semiconductor layer 28. In this case, a center section of the upper surface of the third semiconductor section 28 defines an emission surface 29. The second electrode 232 can be formed from a multilayer film of, for example, Au and an alloy of Au and Zn.

A current can be circulated to the second semiconductor layer 24 that functions as an active layer by the first and second electrodes 230 and 232. It is noted that the materials of the first and second electrodes 230 and 232 are not limited to the above, and metals, such as, for example, Ti, Ni, Au or Pt, or an alloy of these metals can be used.

The rectification element section 240 defines a functional section of the present embodiment, and is formed on a region on the substrate 10 which is different from the light emitting element section 20. The rectification element section 240 has a rectification action. The rectification element section 240 of the present embodiment includes a junction diode 252 (including a zener diode).

More specifically, the rectification element section 240 includes a first supporting section 42 formed with the same composition as that of the first semiconductor section 22, a second supporting section 44 formed with the same composition as that of the second semiconductor section 24, third supporting sections 246 and 248, and fourth semiconductor layers 250 and 260, which are disposed successively from the side of the substrate 10.

The first supporting section 42 may be formed continuously with the first semiconductor layer 22. In other words, the first semiconductor layer 80 may be formed on the substrate 10, a part of the first semiconductor layer 80 may define the first semiconductor section 22, and another part thereof may define the first supporting section 42. Also, the second supporting section 44 may be formed continuously with the second semiconductor layer 24. In other words, a second semiconductor layer 82 may be formed on the first semiconductor layer 80, a part of the second semiconductor layer 82 may define the second semiconductor layer 24, and another part thereof may define the second supporting section 44. Alternatively, the second supporting section 44 may be separated from the second semiconductor layer 24.

The third supporting sections 246 and 248 are formed in a second conductivity type (for example, p-type), and a topmost layer (250) of the fourth semiconductor layers 250 and 260 is formed in a first conductivity type (for example, n-type). Accordingly, a pn junction diode can be formed by a topmost layer (248) of the third supporting sections 246 and 248, the topmost layer (250) of the fourth semiconductor layers 250 and 260, and the fourth semiconductor layer 260 provided therebetween. It is noted that the third supporting sections 246 and 248 both may contribute to operations of the pn junction diode.

The third supporting sections 246 and 248 may be formed in the same composition as that of the third semiconductor layers 26 and 28. In the example shown in FIG. 2, the third supporting section 246 is formed in the same composition as that of the third semiconductor layer 26 that is a mirror, and the third supporting section 248 is formed in the same composition as that of the third semiconductor layer 28 that is a contact section. A topmost layer (248) of the third supporting sections 246 and 248 may be formed from a (for example, p-type) GaAs layer.

In the present embodiment, the topmost layer (250) of the fourth semiconductor layers 250 and 260 is not limited to any particular material, as long as it has a conductivity type different from that of the third supporting sections 246 and 248. For example, the topmost layer (250) of the fourth semiconductor layers 250 and 260 may have a conductivity type different from that of the third supporting sections 246 and 248, and may be formed with the same composition ((for example, n-type) GaAs layer) as that of at least a part of the third supporting sections 246 and 248 (for example, the topmost layer (248) of the third supporting sections 246 and 248).

In the present embodiment, the fourth semiconductor layer 260 functions as a capacitance reducing section. Accordingly, the capacitance of the junction diode 252 can be reduced, such that hindrance by the junction diode 252 against the high-speed driving of the light emitting element section 20 can be prevented. In particular, in the present embodiment, because the rectification element section 240 is connected in parallel with the light emitting element section 20, the capacitances of the light emitting element section 20 and the rectification element section 240 influence as an added value with respect to each other. Therefore, the reduction of the capacitance of the junction diode 252 is very effective in driving the surface-emitting type device at higher speeds.

The fourth semiconductor layer 260 may be provided on a region of a portion of the topmost layer (248) of the third supporting sections 246 and 248 in order to secure an electrical connection region. The material, thickness and area of the fourth semiconductor layer 260 can be decided based on the capacitance value of the junction diode 252. To reduce the capacitance of the junction diode 252, a material having a low relative dielectric constant may preferably be used for the fourth semiconductor layer 260.

When the fourth semiconductor layer 260 is formed from an intrinsic semiconductor, the junction diode 252 can be called a pin diode. It is noted that an intrinsic semiconductor is a semiconductor in which most of the carriers that contribute to electrical conduction are free electrons thermally excited in a conductor from the valence band, or holes in the same number generated in the valence band, and changes in the carrier density due to the presence of impurities and/or lattice defects can be ignored.

Alternatively, the fourth semiconductor layer 260 may be a semiconductor layer of the same conductivity type as that of the topmost layer (248) of the third supporting sections 246 and 248 (for example, p-type), and has an impurity concentration to be doped lower than that of the topmost layer (248) of the third supporting sections 246 and 248 (for example, an impurity concentration lower by one digit or more). Alternatively, the semiconductor layer 260 may be a semiconductor layer of the same conductivity type as that of the topmost layer (250) of the fourth semiconductor layers 250 and 260 (for example, n-type), and has an impurity concentration to be doped lower than that of the topmost layer (250) of the fourth semiconductor layers 250 and 260 (for example, an impurity concentration lower by one digit or more).

It is noted that, to reduce the capacitance of the junction diode 252, the thickness of the fourth semiconductor layer 260 may preferably be made greater, and the area thereof may preferably be made smaller. For example, the fourth semiconductor layer 260 may have a thickness greater than that of the topmost layer (248) of the third supporting sections 246 and 248 (or the topmost layer (250) of the fourth semiconductor layers 250 and 260), and an area smaller than that of the topmost layer (248) of the third supporting sections 246 and 248.

The fourth semiconductor layer 260 may be formed from, for example, an AlGaAs layer, a GaAs layer or the like. If the fourth semiconductor layer 260 is formed from a material different from that of the topmost layer (248) of the third supporting sections 246 and 248 which serves as a ground, a selection ratio in wet etching can be obtained, such that selective etching of the fourth semiconductor layer 260 is easy. For example, when the topmost layer (248) of the third supporting sections 246 and 248 is formed from a GaAs layer, the fourth semiconductor layer 260 may be formed from an AlGaAs layer.

When the fourth semiconductor layer 260 is formed from an AlGaAs layer, the ratio of each composition is not particularly limited, but a higher Al composition ratio may be preferred because the relative dielectric constant of the fourth semiconductor layer 260 can be lowered. The ratio of each composition of an AlGaAs layer of the fourth semiconductor layer 260 may be defined by, for example, AlₓGa₁₋ₓAs (x≧0.3). By this, because the Al composition ratio is high, the capacitance of the junction diode 252 can be further reduced, and a sufficient etching selection ratio can be obtained with respect to the topmost layer (248) of the third supporting sections 246 and 248 which serves as a ground.

Next, the structure of the electrode (wiring pattern) is described.

The first and second electrodes 230 and 232 for driving are formed at the light emitting element section 20. The first electrode 230 is electrically connected to the first semiconductor layer 22, and may be formed on the first semiconductor layer 80. The second electrode 232 is electrically connected to the third semiconductor layers 26 and 28, and may be formed, for example, on the third semiconductor layer 28 that is a contact section. The second electrode 232 may be formed in a ring shape along an end section of the upper surface of the third semiconductor layer 28.

Third and fourth electrodes 234 and 236 for driving are formed at the rectification element section 240. The third electrode 234 is electrically connected to the third supporting sections 246 and 248. For example, the topmost layer (250) of the fourth semiconductor layers 250 and 260 may be formed on a part of the area of the third supporting section 248, and the third electrode 234 may be formed in an exposed area of the third supporting section 248. The third electrode 234 may be formed in the same composition as that of the second electrode 232 that corresponds to the same conductivity type (the second conductivity type (for example, p-type)).

The fourth electrode 236 is electrically connected to the topmost layer (250) of the fourth semiconductor layers 250 and 260, and may be formed, for example, on an upper surface of the topmost layer (250) of the fourth semiconductor layers 250 and 260. Because light is not emitted from the upper surface of the topmost layer (250) of the fourth semiconductor layers 250 and 260, the entire upper surface of the topmost layer (250) of the fourth semiconductor layers 250 and 260 may be covered by the fourth electrode 236. The fourth electrode 236 may be formed in the same composition as that of the first electrode 230 that corresponds to the same conductivity type (the first conductivity type (for example, n-type)).

The junction diode (pin diode) 252 is connected in parallel between the first and second electrodes 230 and 232, and have a rectification action in a reverse direction with respect to the light emitting element section 20. More specifically, the first and third electrodes 230 and 234 are electrically connected by a wiring 270, and the second and fourth electrodes 232 and 236 are electrically connected by a wiring 272.

In the example shown in FIG. 1, the first electrode 230 includes a portion formed in a shape that generally encircles the outer circumference of the light emitting element section 20, such as, for example, in a C shape, and a portion extending in a direction toward the third electrode 234. A major portion of the wiring 270 is disposed in an area over either the first electrode 230 or the third electrode 234.

Method for Manufacturing Optical Semiconductor Element

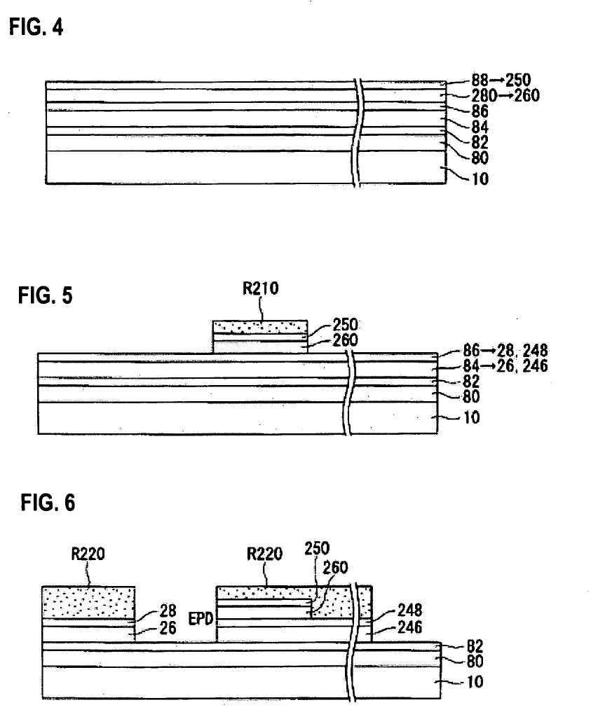

FIG. 4-FIG. 6 are cross-sectional views schematically showing a method for manufacturing an optical semiconductor element in accordance with an embodiment of the invention. In other words, FIG. 4-FIG. 6 show a method for manufacturing the optical semiconductor element 220 shown in FIG. 1-FIG. 3.

As shown in FIG. 4, on a substrate 10, a first semiconductor layer 80 of a first conductivity type (for example, n-type), a second semiconductor layer 82 that functions as an active layer, third semiconductor layers 84 and 86 of a second conductivity type (for example, p-type), and fourth semiconductor layers 88 and 280 are formed by epitaxial growth while varying the composition. The process indicated in FIG. 4 corresponds to a first process in accordance with an embodiment of the invention. The conductivity type and composition of the fourth semiconductor layer 280 correspond to the details of the fourth semiconductor layer 260 described above. Also, the conductivity type and composition of a topmost layer (88) of the fourth semiconductor layers 88 and 280 correspond to the details of the fourth semiconductor layer 250 described above. The details described above may apply to other details of the layers.

Next, as shown in FIG. 5, the fourth semiconductor layers 88 and 280 are patterned to form a portion of a rectification element section (i.e., a functional section) 240. The process indicated in FIG. 5 corresponds to a second process in accordance with the embodiment of the invention. The patterning in the second process is described more concretely below.

As shown in FIG. 5, the fourth semiconductor layers 88 and 280 are patterned. More specifically, resist is coated on the fourth semiconductor layer 88, and the resist is patterned, thereby forming a resist layer R210 having a predetermined pattern. Then, by using the resist layer R210 as a mask, etching is conducted.

In the etching in the second process, dry etching is conducted to form a portion of the rectification element section 240 that defines a functional section, and then wet etching is conducted. By these etching steps, the patterning is conducted as shown in FIG. 5. The dry etching and the wet etching may be continuously conducted.

Also, by the dry etching described above, the entire topmost layer (88) of the fourth semiconductor layers 88 and 280, and a major portion of the fourth semiconductor layer 280 therebelow may preferably be etched. Then, the remaining thin portion of the fourth semiconductor layer 280 may preferably be etched by wet etching. For example, the fourth semiconductor layer 280 may be etched by dry etching until its film thickness becomes to be 0.1 μm or less (for example, 0.05 μm), and then the remaining portion of the fourth semiconductor layer 280 may be etched by wet etching.

By so doing, the amount of etching in the wet etching becomes small, such that disturbances in the pattern configuration which may be caused by etching advancing in a transverse direction (horizontal direction) in the wet etching can be made small. In other words, wet etching causes etching to advance not only in a depth direction but also in a horizontal direction. Therefore, if the entire etching in the second process is conducted by wet etching alone, disturbances in the pattern configuration, such as, an overhang at a side face (boundary) of the etching pattern and the like may occur, which may result in inconvenience such as disconnection of the electrodes, changes in the element capacitance, and the like. In accordance with the present embodiment, the amount of wet etching is small, compared to the amount of dry etching, such that the inconvenience described above can be avoided.

Also, in accordance with the present embodiment, the amount of etching in a depth direction can be accurately controlled by a small amount of wet etching. Therefore, layers that may become to be the rectification element section 240 can be readily and accurately patterned without damaging the third semiconductor layer 86 for forming the light emitting element section 20. It is noted here that the third semiconductor layer 86 becomes to be a third semiconductor layer 28 that defines a contact section which is disposed on a third semiconductor layer 26 that defines a second mirror in the light emitting element section 20. Therefore, if the third semiconductor layer 28 is damaged by etching in the second process, the characteristic of the light emitting element section 20 would be substantially adversely affected. However, in the present embodiment, such adverse effect can be avoided by conducting a small amount of wet etching.

After the fourth semiconductor layers 250 and 260 are formed by the second process, the third semiconductor layers 84 and 86 are patterned, as shown in FIG. 6. More specifically, a resist layer R220 is formed in a similar manner as described above, and etching is conducted by using the resist layer R220 as a mask. By patterning the third semiconductor layer 84, a third semiconductor layer 26 that functions as a mirror, and a third supporting section 246 can be formed, and by patterning the third semiconductor layer 86, a third semiconductor layer 28 that functions as a contact section and a topmost layer (248) of the third supporting sections 246 and 248 can be formed. The process indicated in FIG. 6 corresponds to a third process in accordance with the present embodiment of the invention.

Then, a fourth process for forming first and second electrodes 230 and 232 for driving the light emitting element section 20, and a fifth process for forming a wiring 272 (third electrode) that connects the light emitting element section 20 and the rectification element section 240 are conducted.

Concretely, first, the second semiconductor layer 82 may be patterned. More specifically, a resist layer R220 is formed in a similar manner as described above, and etching is conducted by using the resist layer R220 as a mask, whereby the second semiconductor layer 82 is formed, and at least a portion of the first semiconductor layer 80 is exposed. Accordingly, the first electrode 230 can be formed in an exposed area of the first semiconductor layer 80.

Then, dielectric layers 25 and 45 are formed, and a resin layer 60 is formed. Also, first and second electrodes 230 and 232 for driving the light emitting element section 20 are formed, third and fourth electrodes 234 and 236 for driving the rectification element section 240 are formed, and wirings 270 and 272 (see FIG. 1 and FIG. 2) for electrically connecting predetermined corresponding ones of the electrodes with each other are formed. As a result, an optical semiconductor element 220 in accordance with the present embodiment is completed.

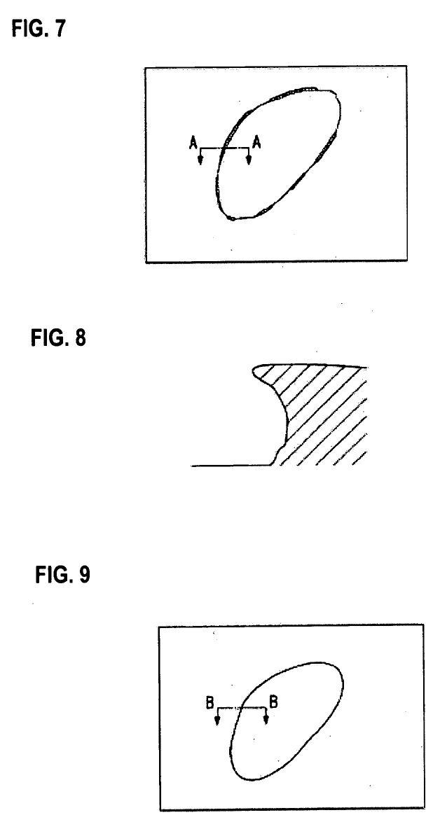

FIG. 7 and FIG. 8 are views showing an example of an etched state when etching in the second process is entirely conducted by wet etching. FIG. 7 is a plan view of an area after the wet etching, and FIG. 8 is a cross-sectional view at a position taken along line A-A in FIG. 7. In FIG. 7, the area inside an oval shape or a bean shape is an area that is not etched (which corresponds to, for example, the fourth semiconductor layers 250 and 260 in FIG. 5). The area outside the oval shape or the bean shape is an area that has been etched by wet etching. The boundary between the area that is etched by wet etching and the area that is not etched by wet etching does not define a vertical cliff, but rather defines an “eaves” shape or a “overhang” shape, as shown in FIG. 8.

This phenomenon occurs because wet etching progresses not only in a depth direction but also in a horizontal direction, such that the side surface configuration at the boundary of the etched pattern is deteriorated. If an “eaves” shown in FIG. 8 is formed, a wiring pattern that traverses the “eaves” section would likely be disconnected. Also, because wet etching causes etching to progress in a horizontal direction, a problem would likely occur in that the etched pattern becomes smaller than its designed size, and the capacitance value given by the fourth semiconductor layer 260 would not become a designed capacitance value.

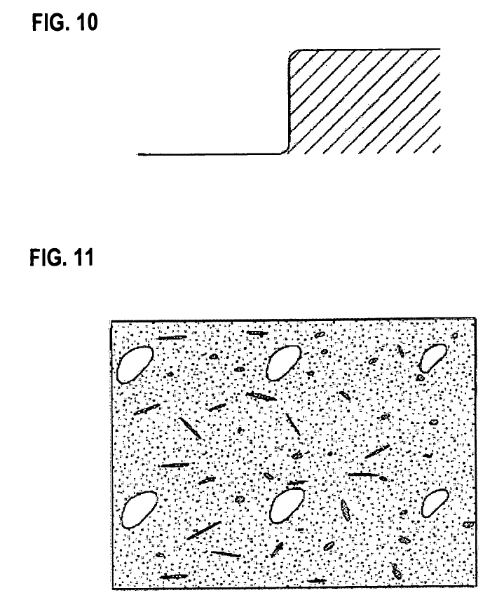

FIG. 9 and FIG. 10 are views showing an example of an etched state when the second process in accordance with the present embodiment is conducted. In other words, the figures show an example of a state in which, in the second process, a major portion of the etching process is conducted by dry etching, and the remaining portion is conducted by wet etching. FIG. 9 is a plan view of an area after the second process, and FIG. 10 is a cross-sectional view at a position taken along line B-B in FIG. 9.

By the etching method in accordance with the present embodiment, the boundary between the area that is etched and the area that is not etched defines a generally vertical cliff. In other words, by the etching method in accordance with the present embodiment, the occurrence of the problem indicated in FIG. 7 and FIG. 8 can be effectively avoided. In other words, through etching the layers that form the rectification element section 240 as much as possible by dry etching, and then continuously conducting wet etching, the advance of etching to the side surface can be held off to a minimum.

In the method for manufacturing an optical semiconductor element in accordance with the present embodiment, a removal step may preferably be conducted between the dry etching and the wet etching in the second process in order to remove a deteriorated layer that is generated by the dry etching.

FIG. 11 is a view showing an example of a state in which a deteriorated layer generated in a dry etching process remains as waste matter. If the deteriorated layer is left remained, the light emitting element section 20 and the rectification element section 240 may not exhibit their desired characteristics. Accordingly, the step of removing the deteriorated layer may preferably be conducted after the dry etching in the second process. As a concrete example of the removal step, a treatment with a mixed solution of ammonia water (NH₄OH) and hydrogen peroxide water (H₂O₂) may be conducted. Alternatively, the removal step may be conducted by ultraviolet ray (UV) irradiation, plasma processing or the like. Also, the deteriorated layer removal step may be included in the wet etching in the second process. In other words, a process that acts to remove the deteriorated layer may be conducted as the wet etching in the second process.

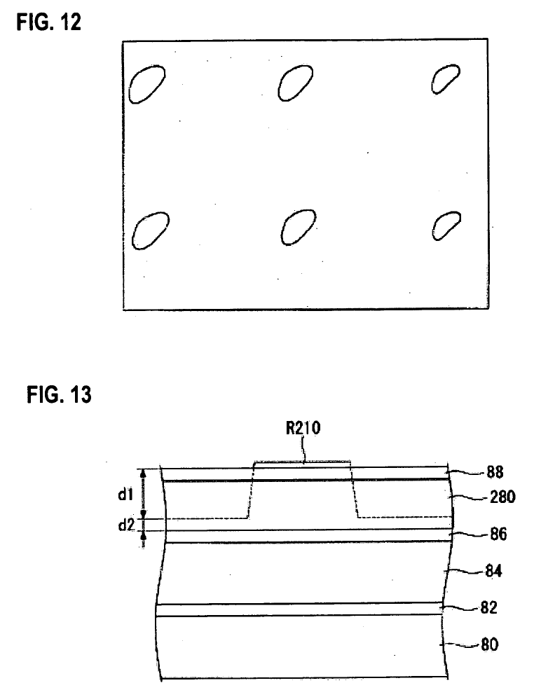

FIG. 12 is a view showing an example of a state in which the step of removing the deteriorated layer has been conducted. FIG. 12 shows that almost no deteriorated layer remains, compared to the state shown in FIG. 11. By removing the deteriorated layer, the performance and reliability of the optical semiconductor element 220 can be improved.

### FIRST EXEMPLARY EMBODIMENT

FIG. 13 is a cross-sectional view schematically showing a method for manufacturing an optical semiconductor element in accordance with a first exemplary embodiment of the invention. The first exemplary embodiment can be considered as a concrete example or a modified example of the method for manufacturing an optical semiconductor element shown in FIG. 4 through FIG. 6. Members in FIG. 13 corresponding to the composing members in FIG. 4 are appended with the same reference numbers.

Each of the layers shown in FIG. 13 can be formed over a substrate by epitaxial growth while varying the composition. A first semiconductor layer 80 is composed of n-type semiconductor, and is a layer for forming a first mirror (first semiconductor layer 22) of a light emitting element section 20. A second semiconductor layer 82 is provided for forming an active layer (second semiconductor layer 24) of the light emitting element section 20. A third semiconductor layer 84 is composed of p-type semiconductor, and is a layer for forming a second mirror (third semiconductor layer 26) of the light emitting element section 20. A third semiconductor layer 86 is composed of p-type GaAs semiconductor, and is a layer for forming a contact section (third semiconductor layer 28) of the light emitting element section 20.

A fourth semiconductor layer 280 is a layer for forming a fourth semiconductor layer 260 of a rectification element section 240. The fourth semiconductor layer 280 may be formed form, for example, a Al_{0.9}Ga_{0.1}As layer. It is noted here that the fourth semiconductor layer 280 is a layer of AlₓGa₁₋ₓAs, where X may preferably be 0.3 or greater. This is so because the etching selection ratio can be made greater by using the difference in aluminum composition. The thickness of the fourth semiconductor layer 280 may be, for example, 0.3 μm-0.8 μm. A topmost layer (88) of the fourth semiconductor layers 88 and 280 is a layer for forming a topmost layer (250) of fourth semiconductor layer 250 and 260 of the rectification element section 240. The topmost layer (88) of the fourth semiconductor layers 88 and 280 may be composed of, for example, n-type GaAs. A resist layer R210 can be used as a mask when etching according to the second process of the embodiment of the invention is conducted.

Then, etching according to the second process of the embodiment of the invention is applied to the laminated structure shown in FIG. 13. More concretely, first, dry etching is conducted. The dry etching may be conducted by using plasma of a mixed gas of, for example, chlorine and argon gas. The dry etching is conducted to a depth indicated by a dotted line in FIG. 13. The depth d1 of the dry etching may be determined according to the thickness of the fourth semiconductor layers 88 and 280, and may be, for example, 0.3 μm-0.7 μm. The thickness d2 of the fourth semiconductor layer 280 which remains after the dry etching may preferably be, for example, 0.1 μm or less, and more preferably, the thickness d2 may be 0.05 μm.

After the dry etching, the deteriorated layer removal step is conducted. The deteriorated layer removal step may be conducted by a treatment with a mixed solution of ammonia water (NH₄OH) and hydrogen peroxide water (H₂O₂). The mixing ratio of ammonia water and hydrogen peroxide water may be, for example, (NH₄OH):(H₂O₂)=1:10. Also, the mixed solution may be diluted with pure water if necessary.

After the deteriorated layer removal step, wet etching is conducted. The wet etching may be conducted with hydrofluoric acid (HF: hydrofluoric acid) with a concentration of 1% or less. By the wet etching, only the fourth semiconductor layer 280 in the thickness d2 can be accurately removed. In other words, the etching can be accurately stopped at the surface of the third semiconductor layer 86 that is a layer for forming the contact section (third semiconductor layer 28). By this, the hindrance to the mirror function of the surface-emitting laser defined by the light emitting element section 20 can be sufficiently avoided. Then, the process indicated in FIG. 6 is conducted, whereby a high performance optical semiconductor element 220 is completed.

### SECOND EXEMPLARY EMBODIMENT

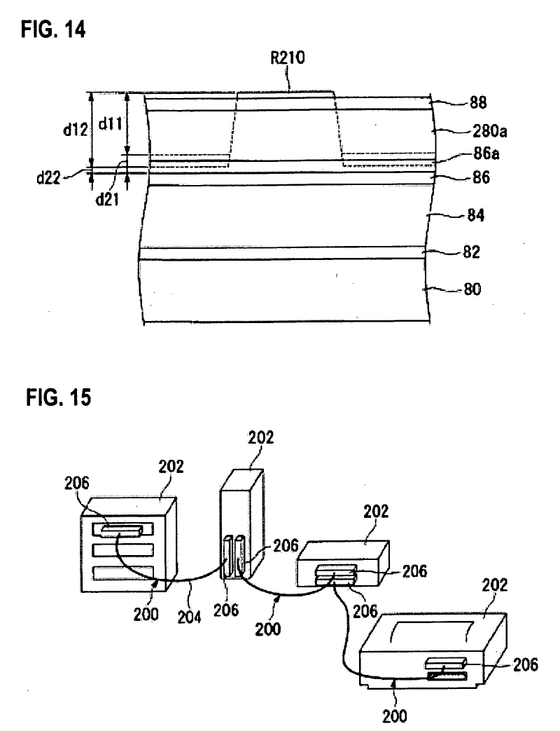

FIG. 14 is a cross-sectional view schematically showing a method for manufacturing an optical semiconductor element in accordance with a second exemplary embodiment of the invention. The second exemplary embodiment can be considered as a concrete example or a modified example of the method for manufacturing an optical semiconductor element shown in FIG. 4 through FIG. 6. Members in FIG. 14 corresponding to the composing members in FIG. 4 are appended with the same reference numbers.

Each of the layers shown in FIG. 14 can be formed over a substrate by epitaxial growth while varying the composition. A first semiconductor layer 80, a second semiconductor layer 82, a third semiconductor layer 84 and a third semiconductor layer 86 are the same as the layers with the same reference numbers in FIG. 13, which form a surface-emitting laser of the light emitting element section 20.

A third semiconductor layer 86a may be formed from, for example, a Al_{0.9}Ga_{0.1}As layer, and has a thickness of 0.05 μm. A fourth semiconductor layer 280a is a layer for forming a fourth semiconductor layer 260 of a rectification element section 240, and may be formed from, for example, a GaAs layer. The fourth semiconductor layer 280a may have a thickness of, for example, 0.3 μm-0.7 μm. A topmost layer (88) of the fourth semiconductor layers 88 and 280a is a layer for forming a topmost layer (250) of fourth semiconductor layers 250 and 260 of the rectification element section 240, and may be composed of, for example, n-type GaAs. A resist layer R210 is used as a mask when etching is conducted according to the second process of the embodiment of the invention.

Etching according to the second process of the embodiment of the invention is applied to the laminated structure shown in FIG. 14. More concretely, first, dry etching is conducted. The dry etching may be conducted by using chlorine, like the first exemplary embodiment. However, the dry etching in this exemplary embodiment may be conducted to a depth of d11 that does not reach the third semiconductor layer 86a, or a depth of d12 that etches a portion of the third semiconductor layer 86a. In this manner, the dry etching of the present exemplary embodiment has a wider permissible depth range than the case of the first exemplary embodiment.

After the dry etching, the deteriorated layer removal step is conducted. The deteriorated layer removal step may be conducted in a manner similar to the deteriorated layer removal step in the first exemplary embodiment. Further, if a portion of the fourth semiconductor layer 280a remains, the remained layer is removed at the same time by this deteriorated layer removal step, and the third semiconductor layer 86a is exposed.

After the deteriorated layer removal step, wet etching is conducted. In this wet etching, etching with a high selection ratio can be conducted by using the difference in material between the third semiconductor layer (GaAs) 86 and the third semiconductor layer (Al_{0.9}Ga_{0.1}As) 86a. In other words, by conducting wet etching with an etchant that etches only Al_{0.9}Ga_{0.1}As, the third semiconductor layer 86 can be more readily and more completely remained. Concretely, the wet etching can be conducted in a manner similar to the wet etching process in the first exemplary embodiment. Therefore, in accordance with the present exemplary embodiment, an optical semiconductor element 220 with higher performance can be more readily manufactured.

Optical Transmission Device

FIG. 15 is a diagram showing optical transmission devices having optical semiconductor elements in accordance with an embodiment of the present invention. The optical transmission devices 200 mutually connect electronic devices 202 such as a computer, a display device, a storage device, a printer and the like. The electronic devices 202 may be information communication devices. The optical transmission device 200 may be provided with a cable 204 and plugs 206 provided on both ends thereof. The cable 204 includes an optical fiber. The plug 206 has a built-in optical semiconductor element 220. The plug 206 may further have a built-in semiconductor chip.

The optical semiconductor element 220 connected to one of the end sections of the optical fiber is an optical semiconductor element in accordance with any one of the embodiments and exemplary embodiments described above, and an optical semiconductor element connected to the other end of the optical fiber is a light-receiving element. Electrical signals outputted from the electronic device 202 on one end are converted to optical signals by the optical semiconductor element 220. The optical signals are transmitted through the optical fiber and inputted in the light-receiving element. The light-receiving element converts the inputted optical signals to electrical signals. Then, the electrical signals are inputted in the electronic device 202 on the other end. In this manner, by the optical transmission device 200 of the present embodiment, information can be transmitted among the electronic devices 202 by optical signals.

Usage Configuration of Optical Transmission Device

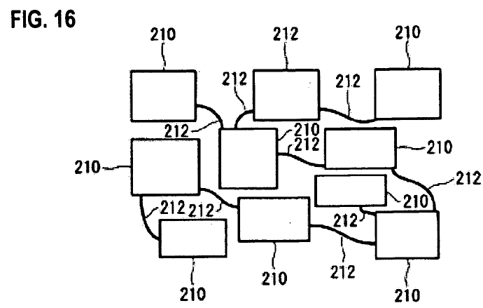

FIG. 16 is a diagram showing a usage configuration of optical transmission devices shown in FIG. 15. Optical transmission devices 212 correspond to the optical transmission devices 200 shown in FIG. 15. The optical transmission devices 212 connect electronic devices 210. The electronic devices 210 may be, for example, liquid crystal display monitors, digital CRTs (which may be used in the fields of finance, mail order, medical treatment, and education), liquid crystal projectors, plasma display panels (PDP), digital TVs, cash registers of retail stores (for POS (Point of Sale Scanning)), videos, tuners, gaming devices, printers and the like.

The technological scope of the invention is not limited to the embodiments described above, and many modifications can be made within the range that does not depart from the subject matter of the invention, and the materials and layer structures enumerated in the embodiments are merely some of examples, and can be appropriately modified.

For example, in the embodiment described above, a diode for electrostatic protection is described as a functional section. However, the invention is not limited to the above, and a diode for monitoring light output may be applied as a functional section.

Further, interchanging the p-type and n-type characteristics of each of the semiconductor layers in the above described embodiments does not deviate from the subject matter of the invention. The aforementioned embodiments are described as using AlGaAs system materials, but other semiconductor materials, such as, for example, GaInNAs system, GaAsSb system, and GaInP system semiconductor materials can be used depending on the oscillation wavelength to be generated.

Optical semiconductor elements in accordance with the embodiments the invention can be widely applied to electronic equipment that use light. Accordingly, as applied circuits or electronic apparatuses equipped with optical semiconductor elements in accordance with the embodiment of the invention, optical interconnection circuits, optical fiber communications modules, laser printers, laser beam projectors, laser beam scanners, linear encoders, rotary encoders, displacement sensors, pressure sensors, gas sensors, blood flow sensors, fingerprint sensors, high-speed electric modulation circuits, wireless RF circuits, cellular phones, wireless LANs and the like can be enumerated.

What is claimed is:

1. A method for manufacturing an optical semiconductor element having a light emitting element section and a functional section, the method comprising: conducting dry etching, and then conducting wet etching, when forming at least a part of the functional section.

2. A method for manufacturing an optical semiconductor element, comprising:
a first process of forming, above a substrate, a first semiconductor layer composed of a first conductivity type, a second semiconductor layer that functions as an active layer, a third semiconductor layer composed of a second conductivity type and a fourth semiconductor layer;
a second process of forming at least a part of a functional section by patterning at least a part of the fourth semiconductor layer;
a third process of forming the functional section and a light emitting element section by patterning at least the third semiconductor layer;
a fourth process of forming first and second electrodes for driving the light emitting element section; and
a fifth process of forming a third electrode that connects the light emitting element section with the functional section,
wherein dry etching is conducted and thereafter wet etching is conducted in the second process to thereby form at least a part of the functional section.

3. A method for manufacturing an optical semiconductor element according to claim 1, wherein the dry etching and the wet etching are continuously conducted.

4. A method for manufacturing an optical semiconductor element according to claim 1, wherein a major part of a designed portion is etched by the dry etching, and a remaining portion of the designed portion is etched by the wet etching.

5. A method for manufacturing an optical semiconductor element according to claim 4, wherein a thickness of the remaining portion to be etched by the wet etching is 0.1 μm or less.

6. A method for manufacturing an optical semiconductor element according to claim 1, wherein a removal step to remove a deteriorated layer that is generated after the dry etching is conducted between the dry etching and the wet etching.

7. A method for manufacturing an optical semiconductor element according to claim 1, wherein the wet etching includes a removal step to remove a deteriorated layer that is generated after the dry etching.

8. A method for manufacturing an optical semiconductor element according to claim 6, wherein the removal step is a process with a mixed solution of ammonia water and hydrogen peroxide water.

9. A method for manufacturing an optical semiconductor element according to claim 6, wherein the removal step is conducted by using ultraviolet ray or plasma.

10. A method for manufacturing an optical semiconductor element according to claim 1, wherein the light emitting element section is a surface-emitting laser, and the functional section is a diode that protects the surface-emitting laser from electrostatic breakdown.

11. A method for manufacturing an optical semiconductor element according to claim 1, wherein the wet etching is conducted using hydrofluoric acid with a concentration of 1% or less.

12. A method for manufacturing an optical semiconductor element according to claim 1, wherein a layer to be removed by the wet etching and a layer below the layer to be removed have different aluminum compositions.

13. A method for manufacturing an optical semiconductor element according to claim 2, wherein the fourth semiconductor layer includes a layer of AlGaAs, and the AlGaAs is expressed by AlₓGa₁₋ₓAs, where X is 0.3 or greater.

14. A method for manufacturing an optical semiconductor element according to claim 2, wherein the fourth semiconductor layer includes a GaAs layer and an AlGaAs layer formed below the GaAs layer, and the AlGaAs layer is thinner than the GaAs layer.

15. An optical semiconductor element manufactured by the method for manufacturing an optical semiconductor element recited in claim 1.
